(19) United States
(12) Patent Application Publication
(10) Pub. No.: US 2024/0203853 A1
(43) Pub. Date: Jun. 20, 2024

(54) DRY FILM PHOTORESIST WET LAMINATION AND METHOD

(71) Applicant: Intel Corporation, Santa Clara, CA (US)

(72) Inventors: Bohan Shan, Chandler, AZ (US); Haobo Chen, Chandler, AZ (US); Hongxia Feng, Chandler, AZ (US); Julianne Troiano, Scottsdale, AZ (US); Dingying Xu, Chandler, AZ (US); Matthew Tingey, Mesa, AZ (US); Xiaoying Guo, Chandler, AZ (US); Srinivas Venkata Ramanuja Pietambaram, Chandler, AZ (US); Bai Nie, Chandler, AZ (US); Gang Duan, Chandler, AZ (US); Bin Mu, Tempe, AZ (US); Kyle Mcelhinny, Tempe, AZ (US); Ashay A. Dani, Chandler, AZ (US); Leonel R. Arana, Phoenix, AZ (US)

(21) Appl. No.: 18/085,281

(22) Filed: Dec. 20, 2022

(51) Int. Cl. H01L 23/498; H01L 21/48; H01L 23/538

(52) U.S. Cl. CPC H01L 23/49827; H01L 21/4846; H01L 23/5384

(57) ABSTRACT

An electronic device and associated methods are disclosed. In one example, the electronic device can include a substrate, a via, a build-up layer, a top layer, and one or more dies. The substrate can include a conductor coating. The via can be connected to the conductor coating. The build-up layer can be on the substrate. The build-up layer can define a channel that the via is formed within and insulate the via during operation of the electronic device. The top layer can be interproximal to the substrate and the via. The one or more dies can be connected to the via.

### TECHNICAL FIELD

Embodiments described herein generally relate to electronic devices. More specifically, embodiments described herein generally relate to electronic devices with dry film photoresist wet lamination and method.

### BACKGROUND

Electronic devices are requiring faster and more efficient components. For example, there is an increased demand for components that can handle high-speed IO (HSPIO) and power delivery. Thus, to accommodate these increased demands, substrates can be made with a larger form factor, higher layer counts, and more aggressive design constraints. The market requirements for components to have HSPIO and power delivery create a great challenge for substrate patterning yield. For example, there can be defects prevalent in substrate manufacturing, e.g., plating under the photoresist layer. Plating under the photoresist layer can include plating in non-designated areas due to the photoresist missing from the non-designated areas before the installment of the plating.

Cores (or panels) can include one or more surface features in the dry film photoresist, e.g., undulations, dents, imperfections, or the like. During the lamination of the dry film photoresist, air can become trapped between the dry film photoresist and the core, which can cause the dry film photoresist not completely to fill in the surface features. The dry film photoresist not filling in the surface features can cause issues, e.g., delamination of the dry film photoresist downstream in electronic device manufacturing. For example, the delamination of the dry film photoresist can also cause unwanted plating in non-designated areas that can cause yield or efficiency issues for downstream manufacturing processes of the electronic devices. It is desired to have electronic devices that address these concerns and other technical challenges.

### BRIEF DESCRIPTION OF THE DRAWINGS

FIG. 1 shows a schematic diagram of an electronic device, in accordance with some example embodiments.

FIG. 2 shows a schematic diagram of a portion of a process to make an electronic device, in accordance with some example embodiments.

FIG. 3 shows an enlarged view of 4-4 from FIG. 2 showing a schematic diagram of a portion of a process to make an electronic device, in accordance with some example embodiments.

FIG. 4 shows a schematic diagram of another process of making an electronic device, in accordance with some example embodiments.

FIG. 5 shows a schematic diagram of a computing device including an electronic device, in accordance with some example embodiments.

FIG. 6 shows a flow diagram of a method of manufacture of an electronic device used in computing devices, in accordance with some example embodiments.

FIG. 7 shows a system that may incorporate an example electronic device made with dry film photoresist and wet lamination and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present disclosure relates to a process and manufacture of an electronic device that can be utilized in high-speed IO and for high-efficiency power delivery. In examples, the electronic device can include a substrate, one or more build-up layer on the substrate, and a top layer. The substrate can include a conductor coating. The top layer can be interproximal to the substrate and a via defined by the build-up layer. In an example, the top layer can be flat on the conductor coating. In another example, the top layer can be flat on the conductor coating such that a thickness of the top layer extends up only a portion of an interior wall of the build-up layer.

The electronic device can be made using a wet lamination process with a high-resolution dry film photoresist layer. In examples, the substrate can be coated with a liquid layer to fill surface features of the substrate. The hydrophobic high-resolution dry film photoresist layer can be laminated onto the substrate over the liquid layer. The hydrophobic high-resolution dry film photoresist layer can absorb the water and swell, such that the hydrophobic high-resolution dry film photoresist fills the surface features. The hydrophobic high-resolution dry film photoresist can be removed selectively to pattern the electronic device and expose the substrate with the conductive coating. The top layer can then be installed on the exposed substrate with the conductive coating, and the hydrophobic high-resolution dry film photoresist can be stripped, leaving an electronic device ready to receive a dielectric layer thereon.

The above discussion is intended to provide an overview of subject matter of the present patent application. It is not intended to provide an exclusive or exhaustive explanation of the invention. The description below is included to provide further information about the present patent application.

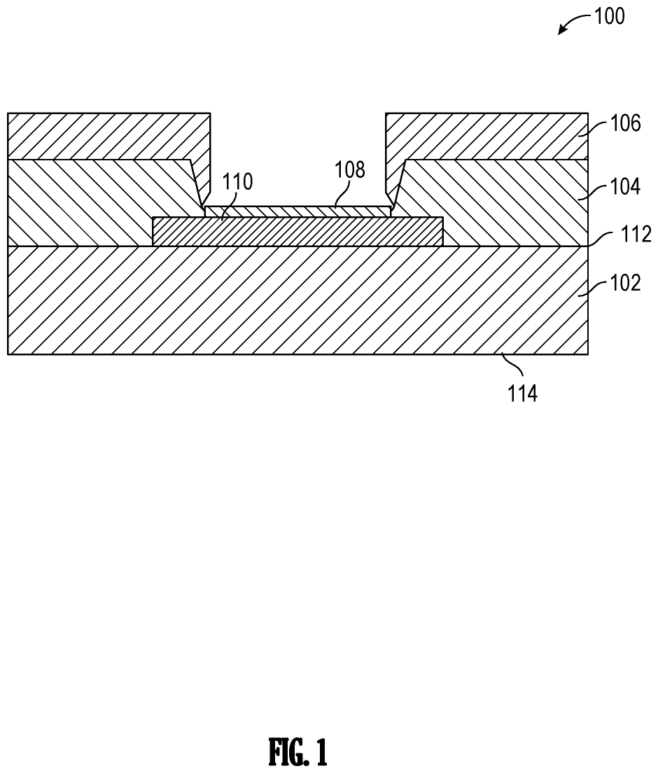

FIG. 1 shows a schematic diagram of an electronic device 100, in accordance with some example embodiments. The device 100 can include a panel or a substrate (substrate 102), a solder resist layer, e.g., solder resist layer 104, a hydrophobic high-resolution dry film photoresist layer (DFR layer 106), and a top layer 108. The substrate 102 can include a conductor coating 110.

The substrate 102 can be configured to support the electronic device 100. In examples, the substrate 102 can be a cored substrate including a first major surface 112 and a second major surface 114. Here, the first major surface and the second major surface can be the surface of the cored substrate that have the largest surface area. The electronic device 100 can include through vias within the cored substrate that extend from the first major surface 112 to the second major surface 114. In examples, the cored substrate can include glass, silicon, any combination of other materials with low electrical conductivity, or the like. In another example, the substrate 102 can be a planar, or panel substrate. The substrate 102 can include vias formed thereon and therethrough.

The solder resist layer 104 can be configured to prevent oxidation or other corrosion and insulate the substrate 102 and the vias formed thereon and through the substrate 102. In examples, the solder resist layer 104 can include polymers, any combination of other materials that can insulate the substrate 102 and the vias, or the like. The solder resist layer 104 can include one or more channels, e.g., channels 116. The channels 116 can define paths for vias to be formed within. The solder resist layer 104 can also include horizontal routings that can connect vias throughout the electronic device 100.

The DFR layer 106 can be configured to control the metal used to form the vias in the electronic device 100. In examples, the DFR layer 106 can be laminated over the solder resist layer 104 after a liquid layer is deposited on the solder resist layer 104. As shown in FIG. 1, the combination of a liquid layer and wet lamination, as will be discussed later, the DFR 106 can extend only a portion of a side wall of the build-up layer 104. As discussed below, the DFR 106 only extending a portion of a side wall of the solder resist layer 104, can permit the top layer 108 to be built up only a portion of the sidewall of the solder resist layer 104.

The DFR layer 106 can be a high-resolution dry film photoresist layer. In examples, the DFR layer 106 can include balanced hydrophobicity. For example, the DFR layer 106 can include high enough hydrophobicity to provide good stability with a fine-line spacing pattern. The DFR layer 106 can also be made from a material that can have a strong enough adhesion to copper of the substrate 102 or the conductor coating 110 such that the DFR layer 106 does not delaminate during the processing of the electronic device 100. The DFR layer 106 can also include a hydrophilicity such that the DFR layer 106 can absorb liquid of a liquid layer. For example, the DFR layer 106 can absorb liquid from the liquid layer and swell to fill surface features on the substrate 102 and the conductor coating 110.

The top layer 108 can be configured to prevent oxidation of the conductive coating, e.g., the conductor coating 110, or the substrate, e.g., the substrate 102, and can include materials to improve the adhesion between the substrate or the conductor coating and the vias. In examples, the top layer 108 can include an electrolytic surface finish to prepare the surface of the conductor coating 110 for attachment to the vias. The top layer 108 can be interproximal to the conductor coating 110 and the via formed within the channels 116 of the solder resist layer 104. The top layer 108 can extend along the conductor coating 110 and only up a portion of the solder resist layer 104. In examples, the top layer 108 can be essentially flat, such that a thickness of the top layer 108 is the only portion of the top layer 108 that extends up internal sidewalls of the solder resist layer 104. In examples, a layer, e.g., the top layer 108 made from electrolytic deposition can be detectable to one of ordinary skill in the art, over other formation techniques. For example, by examining features such as chemistry, grain structure, surface finish, or by testing the mechanical properties of the top layer 108, a person of ordinary skill in the art can detect that the top layer 108 was deposited using electrolytic deposition.

The conductor coating 110 can be deposited onto the substrate 102 to improve adhesion with the vias and improve conductivity between the vias and the substrate 102. For example, the conductor coating 110 can include a coper pad to help form electrical connection within the electronic device 100. The conductor coating 110 can be configured to connect to downstream layers of the electronic device 100. For example, the conductor coating 110 can connect to one or more vias to improve electrical connection between the layers. Thus, the conductor coating 110 can form electrical connection within the electronic device 100. The conductor coating 110 can be interproximal to the substrate 102 and the top layer 108. The conductor coating 110 can include copper, aluminum, any alloy thereof, or combination of materials with electrical and thermal conductivity, or the like.

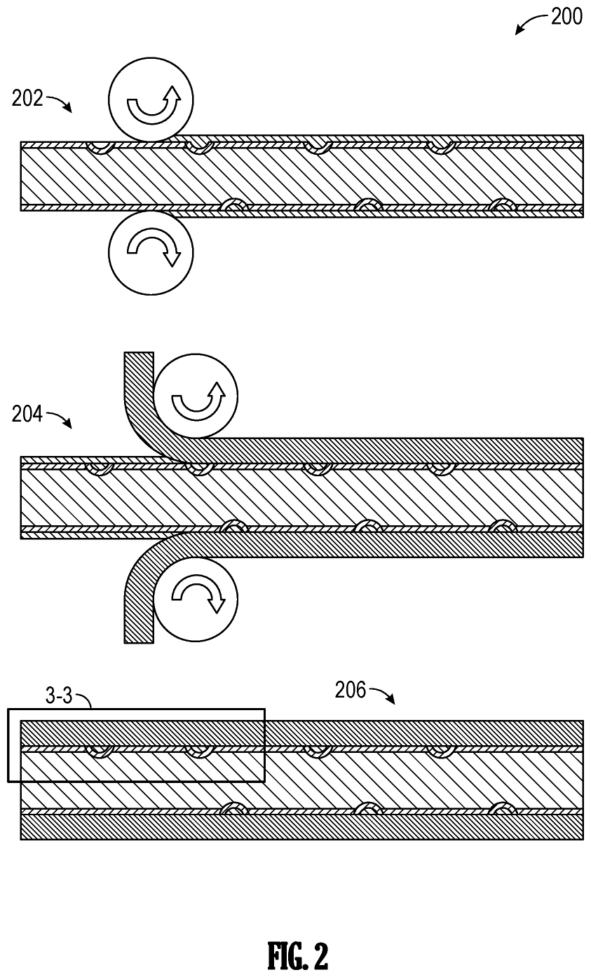

FIG. 2 shows a schematic diagram of a portion of a process 200 to make an electronic device, e.g., the electronic device 100, or a component of an electronic device, in accordance with some example embodiments. The process 200 can be configured to optimize manufacturing efficiency and capabilities of electronic devices, e.g., the electronic device 100 from FIG. 1.

At procedure 202, the process 200 can include coating a layer of liquid on top of the substrate and the conductive coating, e.g., the substrate 102 and the conductive coating 110 from FIG. 1. In the example shown in FIG. 2, the liquid layer is coated on the first major surface and the second major surface of a cored substrate. In another example, the liquid layer can be distributed on any of the first major surface or the second major surface. In yet another example, the liquid layer can be dispensed on a major surface of a planar substrate. In examples, the liquid layer can include water. In another example, the liquid layer can include water, alcohol, acid, detergent, any combination of any other liquid that a high-resolution dry film photoresist layer can absorb, e.g., the DFR layer 106 of FIG. 1. As shown in FIG. 2, rollers can be used to dispense the liquid layer. For example, the rollers can include a foam material that can control an amount of liquid distributed onto the substrate. In another example, the liquid layer can be poured, sprayed, dripped, or dispensed onto the substrate in any other way to dispense a liquid. In an example, the liquid can squeeze or replace the air in the imperfections of the surfaces to reduce air entrapment during lamination of the dry film photo resist layer.

At procedure 204, the process 200 can include laminating a high-resolution dry film photoresist layer, e.g., the DFR layer 106 from FIG. 1. As shown in FIG. 2, the high-resolution dry film photoresist layer can be laminated onto the first major surface and the second major surface of a cored substrate. In another example, the high-resolution dry film photoresist layer can be laminated onto either the first major surface or the second major surface of the cored substrate. In yet another example, the high-resolution dry film photoresist layer can be laminated onto a major planar substrate. As shown in FIG. 2, rollers can be used to laminate the high-resolution photoresist layer. For example, a rubber, polymer, metal, foam, any combination thereof, or the like can laminate the high-resolution dry film photoresist layer onto the liquid layer. For example, the roller hardness and the nip pressure, i.e., a pressure exerted by the roller onto the substrate at the point of lamination, can be adjusted to improve the lamination of the high-resolution dry film photoresist layer onto the liquid layer. For example, a roller with a higher hardness can exert more pressure over a smaller area and a roller with a lower hardness can exert less pressure over a larger area.

At procedure 206, the process 200 can include the high-resolution dry film photoresist layer pushing the liquid from the liquid layer into the surface features of the conductive layer or the substrate to fill the surface features, force air out of the voids created by the surface features, and prevent air from being trapped underneath the high-resolution dry film photoresist layer. For example, the high-resolution dry film photoresist layer can engage the liquid while the high-resolution dry film photoresist layer is being laminated onto the liquid layer. The high-resolution dry film photoresist layer can also apply a pressure to the liquid layer to disperse the liquid caught between the high-resolution dry film photoresist layer and the conductive coating or the substrate. In examples, the process 200 can include a rest time that provides the high-resolution dry film photoresist layer enough time to manipulate the liquid to fill the surface features of the conductive coating or the substrate.

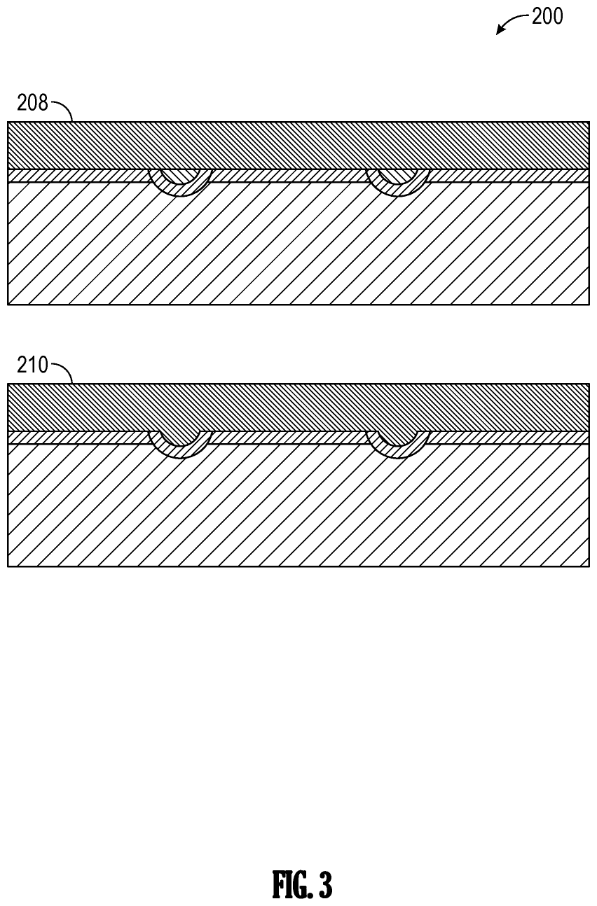

FIG. 3 shows an enlarged view of 3-3 from FIG. 2 showing a schematic diagram of a portion of the process 200 to make an electronic device, e.g., electronic device 100, in accordance with some example embodiments.

At procedure 208, the process 200 can include the high-resolution dry film photoresist layer absorbing liquid from the liquid layer. As discussed above, a balanced hydrophobicity is required for the high-resolution dry film photoresist layer such that the high-resolution dry film photoresist layer can absorb liquid from the liquid layer. The hydrophilicity of the high-resolution dry film photoresist layer can determine the amount of time that the high-resolution dry film photoresist layer is left on the liquid layer to make sure the high-resolution dry film photoresist layer can absorb enough liquid so the high-resolution dry film photoresist layer can swell from the liquid absorption.

At procedure 210, the process 200 can include the high-resolution photoresist layer swelling from the liquid absorbed in procedure 208 of the process 200. The amount of hydrophilicity of the high-resolution dry film photoresist can determine an amount of swelling that occurs during the procedure 210. Thus, the high-resolution dry film photoresist layer can be altered to work with various surface features of the conductive layer or the substrate.

In examples, the process 200 can also be manipulated to control the amount of swelling of the high-resolution dry film photoresist layer by curing the high-resolution dry film photoresist layer with a power source. The power source can be light, heat, or any other source that can cure a high-resolution dry film photoresist layer. For example, the power source can be an ultraviolet light that emits ultraviolet energy that cures the high-resolution dry film photoresist layer. Once the high-resolution dry film photoresist layer is cured, the high-resolution dry film photoresist layer will stop absorbing liquid and swelling resulting from the absorbed liquid. Thus, the depth of filling of the surface features by the high-resolution dry film photoresist layer can be controlled by a resting time before curing the high-resolution dry film photoresist layer. For example, if the resting time is increased, that provides the high-resolution dry film photoresist layer more time to swell into the surface features of the conductive layer or the substrate, and if the resting time is decreased, that provides the high-resolution dry film photoresist layer less time to swell into the surface features of the conductive layer or the substrate.

By using wet lamination compatible DFR, e.g., the DFR layer 106 from FIG. 1, and a wet lamination process, all the trapped air bubbles can be displaced by liquid and can be further absorbed into the DFR. Therefore, lamination-induced DFR yield loss can be significantly reduced. The current laminator tool can be upgraded to add a water dispensing module instead of buying a new tool for wet lamination. Since the wet lamination run rate will be similar to the current hot roller lamination, the cost and throughput impact can be minimal.

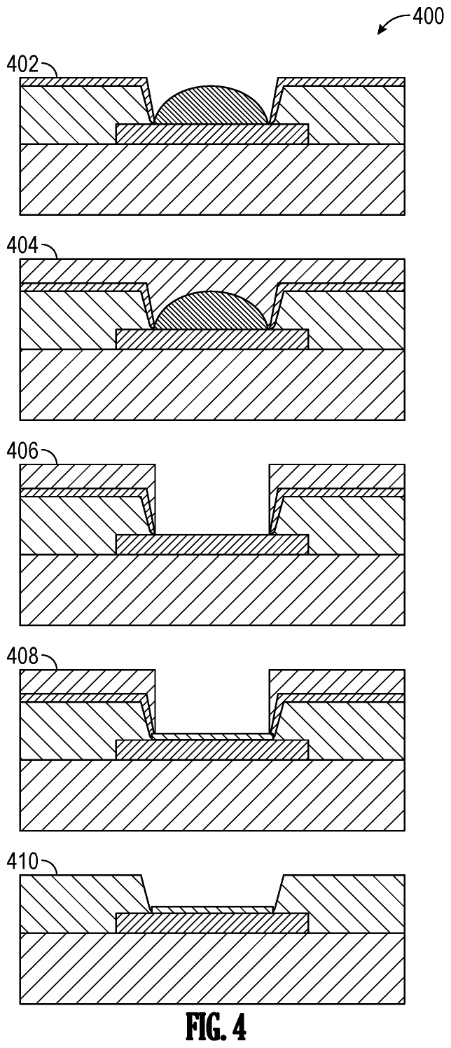

FIG. 4 shows a schematic diagram of a process 400 of making an electronic device, e.g., the electronic device 100 (FIG. 1), in accordance with some example embodiments.

At procedure 402, the process 400 can include selectively depositing a liquid into channels formed in a solder resist layer on a substrate, e.g., the substrate 102 and the solder resist layer 104 of FIG. 1. An amount of liquid can be adjusted to alter the requirements of the high-resolution dry film photoresist layer. For example, more water can be included to increase distance between the high-resolution dry film photoresist layer and the conductor coating or substrate, and less water can be deposited to decrease a distance between the high-resolution dry film photoresist layer and the conductive coating or the substrate. In examples, the liquid can be deposited directly on the conductive coating of the substrate. In another example, the liquid can be deposited directly on the substrate. The liquid can include water, alcohol, or any other liquid that can be absorbed by the high-resolution dry film photoresist layer, or the like. In examples, the hydrophobicity of the high-resolution dry film photoresist layer can be altered to determine an amount of liquid absorbed. For example, a high-resolution dry film photoresist layer can be designed to not absorb water, resulting in a greater gap between the high-resolution dry film photoresist layer because the water fills the void between the high-resolution dry film photoresist layer and the conductive layer or substrate.

At procedure 404, the process 400 can include laminating the high-resolution dry film photoresist layer, e.g., the DFR layer 106 from FIG. 1, on top of the buildup layer, the liquid, the conductive layer, and the substrate. As shown in FIG. 4, the high-resolution dry film photoresist layer can surround the liquid that was deposited within the channel of the buildup layer. Here, all the air is forced out from between the substrate, the conductive coating, and the high-resolution dry film photoresist layer, and that space is filled with either the liquid or the high-resolution dry film photoresist layer. In examples, the high-resolution dry film photoresist layer can be configured not to absorb the liquid deposited within the channel of the buildup layer. Thus, the amount of liquid can determine a distance between the high-resolution dry film photoresist layer and the conductive layer or the substrate. For example, the more liquid deposited within the channel of the buildup layer, the greater the distance between the high-resolution dry film photoresist layer and the conductive coating or the substrate, and the less liquid deposited within the channel of the buildup layer, the greater the distance between the high-resolution dry film photoresist layer and the conductive coating or the substrate.

At procedure 406, the process 400 can include developing the high-resolution dry film photoresist layer and removing any liquid dispensed within the channel of the buildup layer. The selective stripping of the high-resolution dry film photoresist layer can prepare the electronic device for application of the top layer or the surface finishing layer. As shown in FIG. 4, the high-resolution dry film photoresist layer covering the buildup layer can remain intact, such that the non-removed high-resolution dry film photoresist layer can prevent metal buildup on the buildup layer. The high-resolution dry photo resist layer can be stripped in any pattern to match the design requirements of the electronic device.

At procedure 408, the process 400 can include electrolytically depositing a top layer, or a surface layer on the conductive layer or the substrate. The top layer can be configured to prevent oxidation and reduce electron migration within the electronic device. In another example, any process to improve the surface finish of the conductive layer or the substrate can be used to improve adhesion between the metallic via and the substrate or conductive coating.

At procedure 410, the process 400 can include stripping away the rest of the high-resolution dry film photoresist layer. Once the high-resolution dry film photoresist layer is removed, the electronic device can be ready to receive a metallic via to configure the electronic device to work in a computing device.

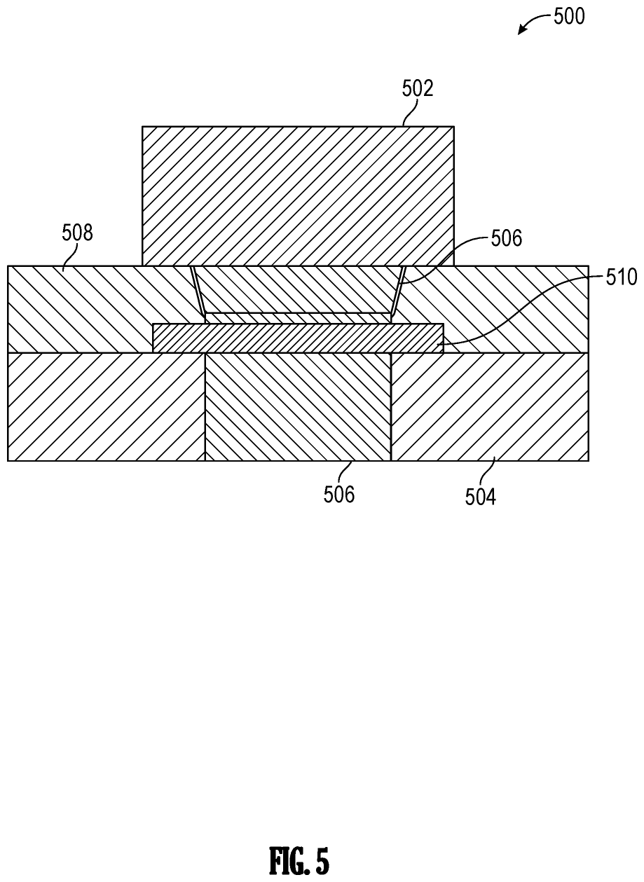

FIG. 5 shows a schematic diagram of a computing device 500, in accordance with some example embodiments. In an example, the computing device 500, e.g., the electronic device 100 from FIG. 1, can be a primary processor for a controller. In another example, the computing device 500 can be a component of a controller. The computing device 500 can include dies 502, a substrate 504, vias 506, solder resist layer 508, and conductive layer 510.

The dies 502 can be coupled to one or more layers of the substrate 504 and connected to the vias 506. A first die of the dies 502 can be connected to a second die of the dies 502 via horizontal routings within, on, or outside of the substrate 504.

The substrate 504, e.g., the substrate 102 from FIG. 1, can be designed to hold multiple dies 502 and permit or block communication between each die of the dies 502 installed on the substrate. In examples, the substrate 504 can be a cored substrate. In another example, the substrate 504 can be a planar substrate.

The vias 506 can be formed on and through the substrate 504. In examples, the vias 506 can be metallic. For example, the vias 506 can include copper, aluminum, any alloy or combination of materials with electrical conductivity, or the like. The vias 506 can enable electronic communication through the substrate 504. The computing device 500 can also include external vias 506 formed in channels of the solder resist layer 508.

The solder resist layer 508 can be built up on the substrate 504. In examples, the solder resist layer 508 can define channels that are filled with metal to form the vias 506. The solder resist layer 508 can help insulate the computing device 500.

The conductive layer 510 can be interproximal the substrate and the metallic vias. The conductive layer 510 can be made of copper or any other material that can improve adhesion between the metallic vias and the substrate.

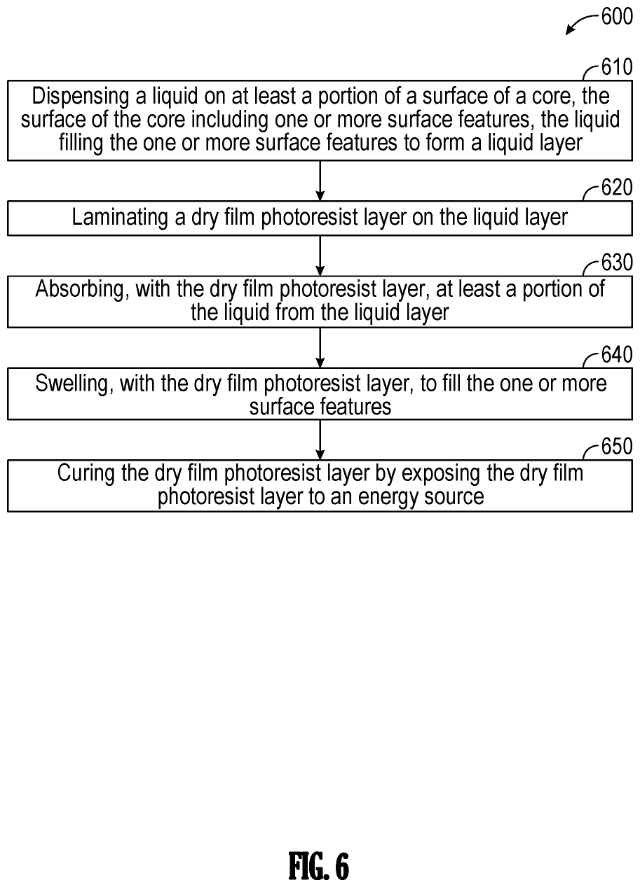

FIG. 6 shows a flow diagram of a method of manufacturing a portion of an example substrate used in electronic devices, in accordance with some example embodiments. More specific examples of the method 600 are discussed below. The steps or operations of the method 600 are illustrated in a particular order for convenience and clarity: many of the discussed operations can be performed in a different sequence or parallel without materially impacting other operations. The method 600 includes operations performed by multiple different actors, devices, or systems. It is understood that subsets of the operations discussed in the method 600 can be attributable to a single actor, device, or system that could be considered a separate standalone process or method.

At process 610, the method 600 can include dispensing a liquid on at least a portion of a surface of a core, e.g., the substrate 102 from FIG. 1. The surface of the core can include one or more surface features. The liquid can fill the one or more surface features to form a liquid layer. In examples, the liquid can be water, oil, a detergent, or any other liquid that can be used to displace air in the surface features of the substrate or the conductive surface. In examples, the liquid can be distributed onto the substrate to create a liquid layer, e.g., process 200, or liquid can be distributed onto the substrate only at a location, e.g., within a channel defined by the build-up layer, that a metallic via will be formed, e.g., the procedure 402 of the process 400.

At process 620, the method 600 can include laminating a dry film photoresist layer, e.g., the DFR layer 106 from FIG. 1, onto the liquid layer. In another example, the method can include laminating the dry film photoresist onto the build-up layer, e.g., the solder resist layer 104 from FIG. 1, and on top of liquid within a channel of the build-up layer. The dry film photo resist layer can be laminated onto the electronic device using any lamination techniques currently used in electronic device manufacturing.

At process 630, the method 600 can include absorbing, with the dry film photoresist layer, at least a portion of the liquid from the liquid layer. The dry film photoresist layer can be configured to absorb a set amount of liquid from the liquid layer. The absorbed liquid can be displaced by the dry film photoresist layer.

At process 640, the method 600 can include swelling, with the dry film photoresist, to fill the one or more surface features. The dry film photoresist layer can be configured to swell upon absorbing liquid from the liquid layer. In examples, the hydrophobicity of the dry film photoresist layer can be altered to accommodate surface features on substrates or conductive layers. An amount of rest time can also be adjusted to affect the absorption and swelling of the dry film photoresist layer. For example, the rest time can be increased to increase an amount of absorption and swelling of the dry film photoresist layer. In another example, the rest time can be decreased to decrease an amount of absorption and swelling of the dry film photoresist layer.

At process 650, the method 600 can include curing the dry film photoresist layer by exposing the dry film photoresist layer to an energy source. For example, the energy source can be ultraviolet light. In another example, the energy source can be a heat source. Once cured, the dry film photoresist layer can stop absorbing water and swelling, thus the cured dry film photoresist can set a distance between the dry film photo resist and a surface of the substrate or the conductive layer.

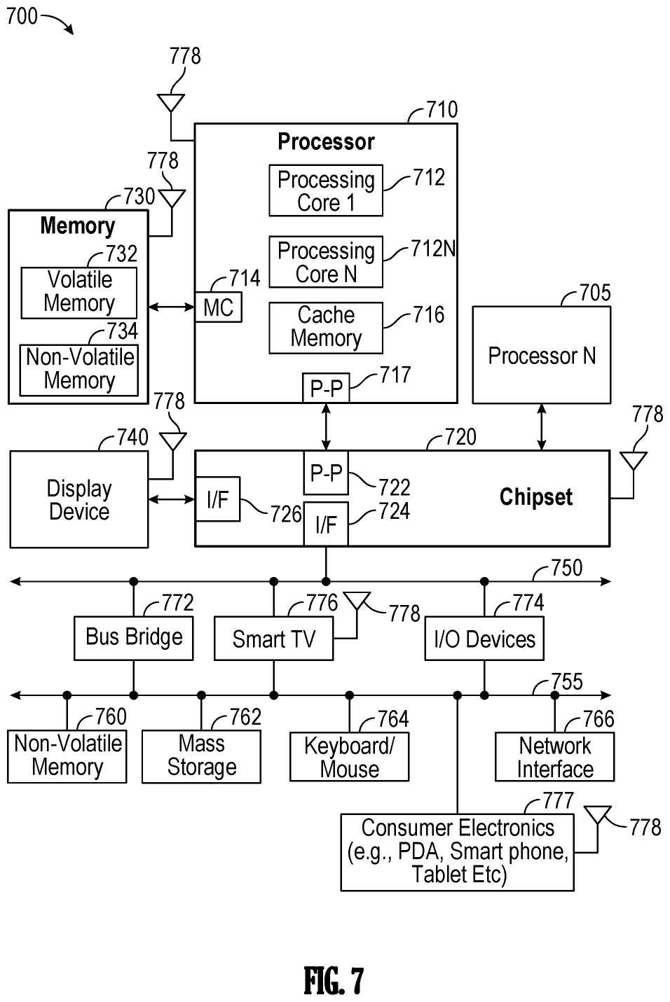

FIG. 7 illustrates a system-level diagram, depicting an example of an electronic device (e.g., system) that may include an example substrate made with dry film photoresist and wet lamination or methods described above. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smartphone, an Internet appliance or any other type of computing device. In some embodiments, system 700 includes a system on a chip (SOC) system.

In one embodiment, processor 710 has one or more processor cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, an interface for wireless antenna 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the example system, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices, including a bus bridge 772, a smart TV 776, I/O devices 774, nonvolatile memory 760, a storage medium (such as one or more mass storage devices) 762, a keyboard/mouse 764, a network interface 766, and various forms of consumer electronics 777 (such as a PDA, smart phone, tablet etc.), etc. In one embodiment, chipset 720 couples with these devices through an interface 724. Chipset 720 may also be coupled to a wireless antenna 778 to communicate with any device configured to transmit and/or receive wireless signals. In one example, any combination of components in a chipset may be separated by a continuous flexible shield as described in the present disclosure.

Chipset 720 connects to display device 740 via interface 726. Display 740 may be, for example, a liquid crystal display (LCD), a light emitting diode (LED) array, an organic light emitting diode (OLED) array, or any other form of visual display device. In some embodiments of the example system, processor 710 and chipset 720 are merged into a single SOC. In addition, chipset 720 connects to one or more buses 750 and 755 that interconnect various system elements, such as I/O devices 774, nonvolatile memory 760, storage medium 762, a keyboard/mouse 764, and network interface 766. Buses 750 and 755 may be interconnected together via a bus bridge 772.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

To better illustrate the method and apparatuses disclosed herein, a non-limiting list of embodiments is provided here:
Example 1 is an electronic device comprising: a cored substrate including a conductor coating extending along at least one of a first major surface or a second major surface: a through via extending through the cored substrate from the first major surface to the second major surface, the through via connected to the conductor coating: an external via external to the cored substrate, the external via connected to the conductor coating: a solder resist layer on the cored substrate, the solder resist layer defines a channel that the external via is formed within and insulates the external via: a top layer, the top layer including gold to prevent oxidation and prepare the conductor coating to adhere to the external via, the top layer extending along the conductor coating and only a portion of the solder resist layer: and one or more dies connected to the external via.
In Example 2, the subject matter of Example 1 includes, wherein the top layer includes an electrolytic layer.
In Example 3, the subject matter of Examples 1-2 includes, wherein the cored substrate includes glass.
In Example 4, the subject matter of Examples 1-3 includes, wherein the conductor coating includes copper.
Example 5 is an electronic device comprising: a substrate including a conductor coating: a via connected to the conductor coating: a solder resist layer on the substrate, the solder resist layer defining a channel that the via is formed within and insulating the via during operation of the electronic device; a top layer interproximal to the substrate and the via: and one or more dies connected to the via.
In Example 6, the subject matter of Example 5 includes, wherein the top layer includes an electrolytic layer.
In Example 7, the subject matter of Example 6 includes, wherein the top layer covers the conductor coating.
In Example 8, the subject matter of Example 7 includes, wherein the top layer includes a flat layer such that the top layer does not extend upward along the solder resist layer.
In Example 9, the subject matter of Examples 7-8 includes, wherein the top layer covers only a portion of the solder resist layer.
In Example 10, the subject matter of Examples 5-9 includes, wherein the substrate is a cored substrate, and wherein the cored substrate includes glass.
In Example 11, the subject matter of Examples 5-10 includes, wherein the conductor coating includes copper.
In Example 12, the subject matter of Examples 5-11 includes, wherein the via includes copper.
Example 13 is a method of making a substrate for an electronic device comprising: dispensing a liquid on at least a portion of a surface of a core, the surface of the core including one or more surface features, the liquid filling the one or more surface features to form a liquid layer: laminating a dry film photoresist layer on the liquid layer; absorbing, with the dry film photoresist layer, at least a portion of the liquid from the liquid layer: swelling, with the dry film photoresist layer, to fill the one or more surface features: and curing the dry film photoresist layer by exposing the dry film photoresist layer to an energy source.
In Example 14, the subject matter of Example 13 includes, depositing a solder resist layer on the core: and patterning the solder resist layer to remove the solder resist layer and expose the core.
In Example 15, the subject matter of Example 14 includes, wherein depositing the solder resist layer includes depositing the solder resist layer adjacent to the core such that the solder resist layer is interproximal to the core and the dry film photoresist layer.
In Example 16, the subject matter of Example 15 includes, patterning the dry film photoresist layer to selectively remove the dry film photoresist layer and expose the core: depositing a top layer on the exposed core; and stripping, selectively, the dry film photoresist layer such that the solder resist layer and the top layer are exposed to receive vias.
In Example 17, the subject matter of Example 16 includes, wherein depositing the top layer on the exposed core includes electrolytically depositing the top layer.
In Example 18, the subject matter of Example 17 includes, wherein electrolytically depositing the top layer includes depositing the top layer across the core and only on a portion of the solder resist layer.
In Example 19, the subject matter of Examples 13-18 includes, wherein dispensing on the core includes dispensing on a glass core.
In Example 20, the subject matter of Examples 13-19 includes, wherein dispensing the liquid includes dispensing water.
Example 21 is at least one machine-readable medium including instructions that, when executed by processing circuitry, cause the processing circuitry to perform operations to implement of any of Examples 1-20.
Example 22 is an apparatus comprising means to implement of any of Examples 1-20.
Example 23 is a system to implement of any of Examples 1-20.
Example 24 is a method to implement of any of Examples 1-20.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic device comprising:
a cored substrate including a conductor coating extending along at least one of a first major surface or a second major surface;
a through via extending through the cored substrate from the first major surface to the second major surface, the through via connected to the conductor coating;
an external via external to the cored substrate, the external via connected to the conductor coating;
a solder resist layer on the cored substrate, the solder resist layer defines a channel that the external via is formed within and insulates the external via;
a top layer, the top layer including gold to prevent oxidation and prepare the conductor coating to adhere to the external via, the top layer extending along the conductor coating and only a portion of the solder resist layer; and
one or more dies connected to the external via.

2. The electronic device of claim 1, wherein the top layer includes an electrolytic layer.

3. The electronic device of claim 1, wherein the cored substrate includes glass.

4. The electronic device of claim 1, wherein the conductor coating includes copper.

5. An electronic device comprising:
a substrate including a conductor coating;
a via connected to the conductor coating;
a solder resist layer on the substrate, the solder resist layer defining a channel that the via is formed within and insulating the via during operation of the electronic device;
a top layer interproximal to the substrate and the via; and
one or more dies connected to the via.

6. The electronic device of claim 5, wherein the top layer includes an electrolytic layer.

7. The electronic device of claim 6, wherein the top layer covers the conductor coating.

8. The electronic device of claim 7, wherein the top layer includes a flat layer such that the top layer does not extend upward along the solder resist layer.

9. The electronic device of claim 7, wherein the top layer covers only a portion of the solder resist layer.

10. The electronic device of claim 5, wherein the substrate is a cored substrate, and wherein the cored substrate includes glass.

11. The electronic device of claim 5, wherein the conductor coating includes copper.

12. The electronic device of claim 5, wherein the via includes copper.

13. A method of making a substrate for an electronic device comprising:
dispensing a liquid on at least a portion of a surface of a core, the surface of the core including one or more surface features, the liquid filling the one or more surface features to form a liquid layer;
laminating a dry film photoresist layer on the liquid layer;
absorbing, with the dry film photoresist layer, at least a portion of the liquid from the liquid layer;
swelling, with the dry film photoresist layer, to fill the one or more surface features; and
curing the dry film photoresist layer by exposing the dry film photoresist layer to an energy source.

14. The method of claim 13, comprising:
depositing a solder resist layer on the core; and
patterning the solder resist layer to remove the solder resist layer and expose the core.

15. The method of claim 14, wherein depositing the solder resist layer includes depositing the solder resist layer adjacent to the core such that the solder resist layer is interproximal to the core and the dry film photoresist layer.

16. The method of claim 15, comprising:
patterning the dry film photoresist layer to selectively remove the dry film photoresist layer and expose the core;
depositing a top layer on the exposed core; and
stripping, selectively, the dry film photoresist layer such that the solder resist layer and the top layer are exposed to receive vias.

17. The method of claim 16, wherein depositing the top layer on the exposed core includes electrolytically depositing the top layer.

18. The method of claim 17, wherein electrolytically depositing the top layer includes depositing the top layer across the core and only on a portion of the solder resist layer.

19. The method of claim 13, wherein dispensing on the core includes dispensing on a glass core.

20. The method of claim 13, wherein dispensing the liquid includes dispensing water.
